(19) United States
(12) Patent Application Publication
(10) Pub. No.: US 2026/0357424 A1
(43) Pub. Date: Nov. 12, 2026

(54) FILM-FORMING METHOD AND FILM-FORMING APPARATUS

(71) Applicant: Tokyo Electron Limited, Tokyo (JP)

(72) Inventors: Hiroki MIURA, Iwate (JP); Masato KOAKUTSU, Iwate (JP); Ren MUKOUYAMA, Iwate (JP)

(21) Appl. No.: 19/657,849

(22) Filed: Apr. 24, 2026

(30) Foreign Application Priority Data
May 9, 2025 (JP) 2025-078367

(51) Int. Cl. C23C 16/455; C23C 16/04; C23C 16/40; C23C 16/52

(52) U.S. Cl. CPC C23C 16/45527; C23C 16/045; C23C 16/401; C23C 16/45544; C23C 16/45553; C23C 16/52

(57) ABSTRACT

A film-forming method includes supplying a first silicon raw material to a substrate having a recess such that the first silicon raw material is adsorbed selectively onto an upper portion of the recess; supplying a second silicon raw material to the substrate such that the second silicon raw material is absorbed onto a region of the recess where the first silicon raw material is not absorbed; oxidizing the second silicon raw material adsorbed onto the recess by supplying an oxidizing agent to the substrate; and repeatedly performing, in sequence, the adsorption of the first silicon raw material, the adsorption of the second silicon raw material, and the oxidization of the second silicon raw material.

### CROSS-REFERENCE TO RELATED APPLICATIONS

This application is based upon and claims priority to Japanese Patent Application No. 2025-078367, filed on May. 9, 2025, the entire contents of which are incorporated herein by reference.

### BACKGROUND

### 1. Field of the Invention

The present disclosure relates to a film-forming method and a film-forming apparatus.

### 2. Description of the Related Art

Japanese Patent Application Publication No. 2018-010950 discloses that, when filling a silicon nitride film into a recess formed in a substrate, a chlorine-containing gas is physically adsorbed to a predetermined region from the uppermost portion of the recess to a predetermined depth of the recess, thereby forming a non-adsorptive site for a silicon-containing gas in the predetermined region.

### SUMMARY

A film-forming method according to an aspect of the present disclosure includes: supplying a first silicon raw material to a substrate having a recess such that the first silicon raw material is adsorbed selectively onto an upper portion of the recess; supplying a second silicon raw material to the substrate such that the second silicon raw material is absorbed onto a region of the recess where the first silicon raw material is not absorbed; oxidizing the second silicon raw material adsorbed onto the recess by supplying an oxidizing agent to the substrate; and repeatedly performing the adsorption of the first silicon raw material, the adsorption of the second silicon raw material, and the oxidization of the second silicon raw material such that the adsorption of the first silicon raw material is followed by the adsorption of the second silicon raw material, and the adsorption of the second silicon raw material is followed by the oxidization of the second silicon raw material.

### BRIEF DESCRIPTION OF THE DRAWINGS

FIG. 1 is a schematic cross-sectional diagram of a film-forming apparatus according to an embodiment of the present disclosure.

FIG. 2 is a schematic plan diagram of the film-forming apparatus of FIG. 1.

FIG. 3 is a cross-sectional diagram (1) of a first example of a film-forming method according to an embodiment of the present disclosure.

FIG. 4 is a cross-sectional diagram (2) of the first example of the film-forming method according to the embodiment.

FIG. 5 is a cross-sectional diagram of a second example of the film-forming method according to the embodiment.

### DETAILED DESCRIPTION OF THE DISCLOSURE

The present disclosure provides a technique of controlling a fill profile when filling a silicon oxide film into a recess.

Hereinafter, non-limiting exemplary embodiments of the present disclosure will be described with reference to the drawings. In the drawings, the same or corresponding members or components are denoted by the same or corresponding reference signs, and duplicate descriptions thereof will be omitted.

### Film-forming apparatus

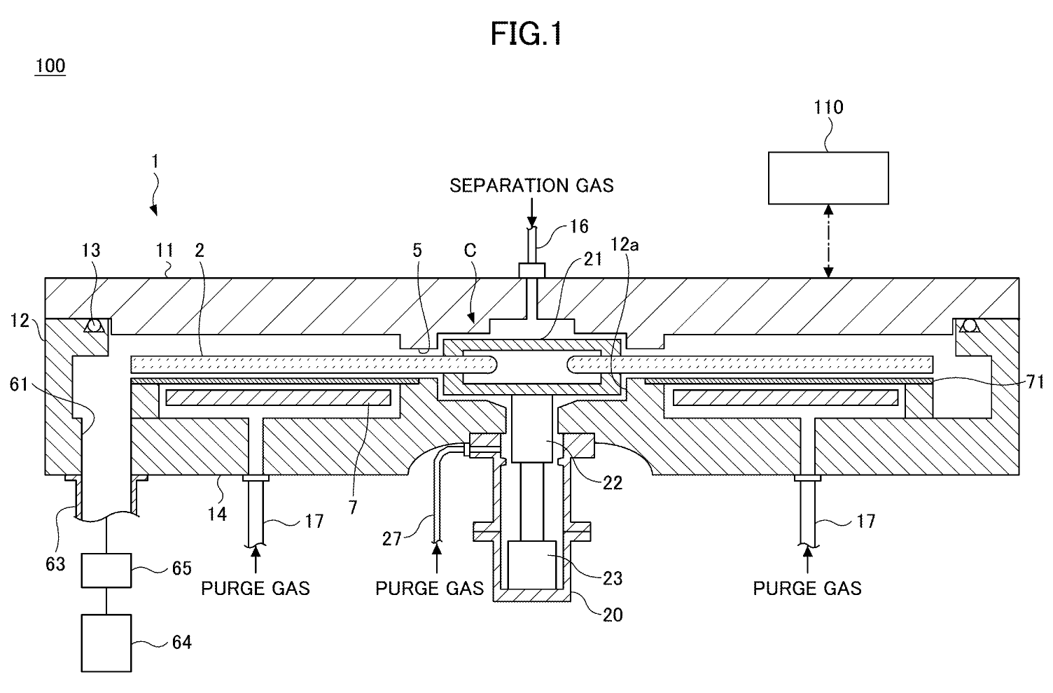

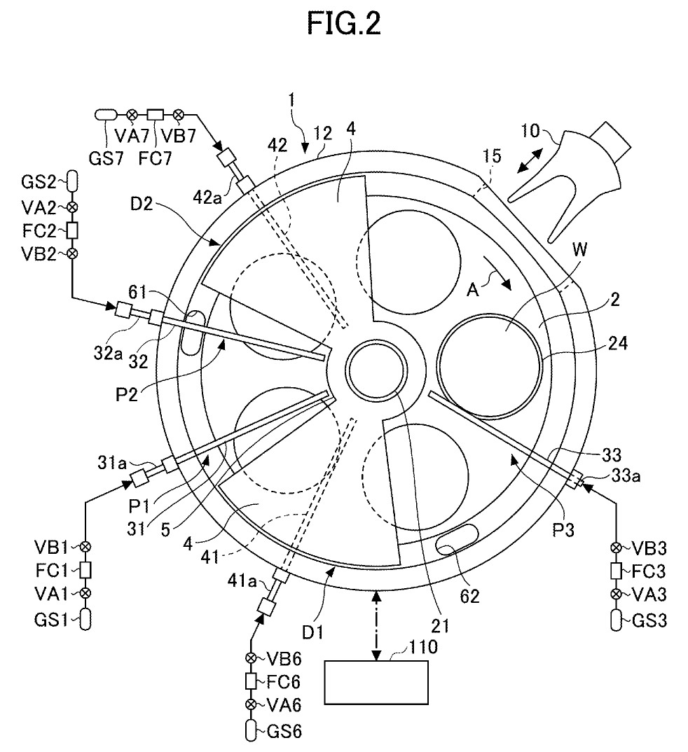

FIG. 1 is a schematic cross-sectional diagram of a film-forming apparatus 100 according to an embodiment of the present disclosure. FIG. 2 is a schematic plan diagram of the film-forming apparatus 100 of FIG. 1. In FIG. 2, illustration of a top plate 11 is omitted for the sake of convenience of description.

The film-forming apparatus 100 includes a substantially cylindrical processing chamber 1, and a rotary table 2 configured to rotate a substrate W in the processing chamber 1. The substrate W is, for example, a semiconductor wafer. The film-forming apparatus 100 includes a controller 110 configured to control the components of the film-forming apparatus 100.

The processing chamber 1 includes therein a processing section configured to store a plurality of substrates W and form a silicon oxide film over each substrate W. The processing chamber 1 includes the top plate 11, a chamber body 12, and a sealing member 13. The top plate 11 is detachably provided to the chamber body 12. The sealing member 13 has an annular shape, and is provided on the upper surface of an outer circumferential wall of the chamber body 12. Thus, the top plate 11 is airtightly fixed to the chamber body 12. The sealing member 13 is, for example, an O-ring.

A separation gas supply tube 16 configured to supply a separation gas, such as a nitrogen (N₂) gas, an argon (Ar) gas, or the like, is connected to the center of the top plate 11. A plurality of purge gas supply tubes 17 configured to supply a purge gas, such as a nitrogen gas, an argon gas, or the like, are connected to a bottom surface 14 of the chamber body 12. The plurality of purge gas supply tubes 17 are provided along the circumferential direction of the bottom surface 14. The bottom surface 14 includes an annular projecting portion 12a at a position near the outer circumferential surface of a core 21 configured to fix the rotary table 2.

The outer circumferential wall of the processing chamber 1 is provided with: a transfer port 15 through which the substrate W is delivered between the rotary table 2 and a transfer arm 10; and a gate valve (not shown) configured to open and close the transfer port 15. The gate valve airtightly seals the processing section of the processing chamber 1 with the transfer port 15 being closed. The rotary table 2 is configured to position a stage 24, on which the substrate W is to be placed, at a position near the transfer port 15, and to transfer the substrate W to and from the transfer arm 10.

The rotary table 2 is housed in the processing chamber 1. The rotary table 2 is fixed to the substantially disk-shaped core 21 at the center of the processing chamber 1. The core 21 is connected to a rotation shaft 22 extending in the vertical direction. The rotation shaft 22 is supported by a driver 23. The driver 23 is configured to rotate the rotary table 2 about a vertical axis (clockwise in FIG. 2) using the rotation shaft 22.

The driver 23 and the lower end of the rotation shaft 22 are housed in a casing 20. The casing 20 is airtightly attached to the bottom surface 14 of the processing chamber 1. A purge gas supply tube 27 configured to supply a purge gas to a lower region of the rotary table 2 is connected to the casing 20.

The rotary table 2 includes, for example, a plurality (five in the illustrated example) of circular stages 24 configured to receive the substrate W having a diameter of 300 millimeters (mm). The plurality of stages 24 are provided at equal intervals along the rotation direction of the rotary table 2. Each stage 24 has an inner diameter that is slightly greater (by about 1 mm or more and about 4 mm or less) than the diameter of the substrate W. The depth of the stage 24 is set to be equal to or greater than the thickness of the substrate W.

The bottom surface of the stage 24 is provided with a plurality (e.g., three) of through-holes (not shown) configured to allow passage of a plurality of raising and lowering pins (not shown). Each raising and lowering pin is provided at a delivery position of the substrate W near the transfer port 15, and is configured to be raised and lowered in an up-down direction by a raising and lowering mechanism (not shown). Each raising and lowering pin is configured to be raised after entry of the transfer arm 10 holding the substrate W to receive the substrate W, and to be lowered after retraction of the transfer arm 10 to place the substrate W on the stage 24. Each raising and lowering pin is configured to raise the substrate W having undergone substrate processing, and to deliver the substrate W to the transfer arm 10 that enters afterwards.

Above the rotary table 2, processing gas nozzles 31, 32, and 33 and separation gas nozzles 41 and 42 are disposed at intervals in the circumferential direction of the processing chamber 1. In the illustrated example, the processing gas nozzle 33, the separation gas nozzle 41, the processing gas nozzle 31, the processing gas nozzle 32, and the separation gas nozzle 42 are disposed sequentially clockwise (the rotation direction indicated by an arrow A in FIG. 2) from the transfer port 15, which will be described below. The processing gas nozzles 31, 32, and 33 and the separation gas nozzles 41 and 42 are formed, for example, of quartz. In the processing gas nozzles 31, 32, and 33 and the separation gas nozzles 41 and 42, their base ends, i.e., gas inlet ports 31a, 32a, 33a, 41a, and 42aare fixed to the outer circumferential wall of the chamber body 12. Thus, the processing gas nozzles 31, 32, and 33 and the separation gas nozzles 41 and 42 are introduced into the processing chamber 1 from the outer circumferential wall of the processing chamber 1, and are attached to extend horizontally with respect to the rotary table 2 along the radial direction of the chamber body 12.

The processing gas nozzle 31 includes a plurality of gas holes (not shown) on the lower surface side (facing the rotary table 2). The processing gas nozzle 31 is connected to a supply source GS1, configured to be charged with a first silicon raw material, outside the processing chamber 1. The processing gas nozzle 31 is configured to jet the first silicon raw material from the supply source GS1 into a first processing region P1, which is below the processing section, through the gas holes. The flow rate of the first silicon raw material from the supply source GS1 is controlled by a flow rate controller FC1. The supply and stop of the first silicon raw material from the supply source GS1 into the processing chamber 1 are controlled by valves VA1 and VB1. A supply source configured to be charged with another gas, e.g., a dilution gas, such as an argon gas or the like, may be further connected to the processing gas nozzle 31.

The processing gas nozzle 32 includes a plurality of gas holes (not shown) on the lower surface side (facing the rotary table 2). The processing gas nozzle 32 is connected to a supply source GS2, configured to be charged with a second silicon raw material, outside the processing chamber 1. The processing gas nozzle 32 is configured to jet the second silicon raw material from the supply source GS2 into a second processing region P2, which is below the processing section, through the gas holes. The flow rate of the second silicon raw material from the supply source GS2 is controlled by a flow rate controller FC2. The supply and stop of the second silicon raw material from the supply source GS2 into the processing chamber 1 are controlled by valves VA2 and VB2. A supply source configured to be charged with another gas, e.g., a dilution gas, such as an argon gas or the like, may be further connected to the processing gas nozzle 32. For example, the processing gas nozzle 32 is disposed next to the processing gas nozzle 31 along the rotation direction of the rotary table 2.

The processing gas nozzle 33 includes a plurality of gas holes (not shown) on the lower surface side (facing the rotary table 2). The processing gas nozzle 33 is connected to a supply source GS3, configured to be charged with an oxidizing agent, outside the processing chamber 1. The processing gas nozzle 33 is configured to jet the oxidizing agent from the supply source GS3 to a third processing region P3, which is below the processing section, through the gas holes. The flow rate of the oxidizing agent from the supply source GS3 is controlled by a flow rate controller FC3. The supply and stop of the oxidizing agent from the supply source GS3 into the processing chamber 1 are controlled by valves VA3 and VB3. The oxidizing agent is, for example, an ozone (O₃) gas or a gas mixture of a hydrogen gas and an oxygen gas. A supply source configured to be charged with another gas, e.g., a dilution gas, such as an argon gas or the like, may be further connected to the processing gas nozzle 33.

The separation gas nozzle 41 forms a separation region D1 that exists between the first processing region P1 and the third processing region P3. The separation gas nozzle 41 includes a plurality of gas holes (not shown) on the lower surface side (facing the rotary table 2). The separation gas nozzle 41 is connected to a supply source GS6 configured to be charged with the separation gas. The separation gas nozzle 41 is configured to jet the separation gas from the supply source GS6 into the separation region D1, which is below the processing section, through the gas holes. The flow rate of the separation gas from the supply source GS6 is controlled by a flow rate controller FC6. The supply and stop of the separation gas from the supply source GS6 into the processing chamber 1 are controlled by valves VA6 and VB6. The separation gas is, for example, an inert gas, such as a nitrogen gas, an argon gas, or the like.

The separation gas nozzle 42 forms a separation region D2 that exists between the second processing region P2 and the third processing region P3. The separation gas nozzle 42 includes a plurality of gas holes (not shown) on the lower surface side (facing the rotary table 2). The separation gas nozzle 42 is connected to a supply source GS7 configured to be charged with the separation gas. The separation gas nozzle 42 is configured to jet the separation gas from the supply source GS7 to the separation region D2, which is below the processing section, through the gas holes. The flow rate of the separation gas from the supply source GS7 is controlled by a flow rate controller FC7. The supply and stop of the separation gas from the supply source GS7 into the processing chamber 1 are controlled by valves VA7 and VB7. The separation gas is, for example, an inert gas, such as a nitrogen gas, an argon gas, or the like.

Substantially fan-shaped projecting portions 4 are provided on the rear surface of the top plate 11 of the processing chamber 1 in the separation regions D1 and D2. The projecting portions 4 project downward from the rear surface of the top plate 11. The projecting portions 4 include radially extending grooves (not shown) at the center in the circumferential direction, and are configured to house the separation gas nozzles 41 and 42 in the grooves.

A projecting portion 5, formed in a substantially annular shape along the circumferential direction, is provided at the center of the lower surface of the top plate 11 to be continuous with the projecting portions 4 closer to a center region C. The lower surface of the projecting portion 5 is formed at the same height as the lower surfaces of the projecting portions 4.

The bottom surface 14 of the processing chamber 1 is provided with a first gas exhaust port 61 and a second gas exhaust port 62. The first gas exhaust port 61 is provided between the processing gas nozzle 31 and the separation region D2. The second gas exhaust port 62 is provided between the processing gas nozzle 33 and the separation region D1. The first gas exhaust port 61 mainly exhausts the first silicon raw material, the second silicon raw material, and the separation gas, and the second gas exhaust port 62 mainly exhausts the oxidizing agent and the separation gas. The first gas exhaust port 61 and the second gas exhaust port 62 are connected to an exhauster 64, such as a vacuum pump or the like, through a gas exhaust tube 63. The gas exhaust tube 63 is provided with a pressure controller 65, such as a butterfly valve or the like.

The film-forming apparatus 100 includes a heater 7 in a space between the rotary table 2 and the bottom surface 14 of the processing chamber 1. The heater 7 is housed in a cover 71 supported by the projecting portion 12a of the chamber body 12. The heater 7 is configured to heat the substrate W on the rotary table 2 to a predetermined temperature.

The controller 110 is an electronic circuit, such as a CPU (Central Processing Unit), an FPGA (Field Programmable Gate Array), an ASIC (Application Specific Integrated Circuit), or the like. The controller 110 is configured to execute various control operations described in the present specification by executing instruction codes stored in a memory or by being designed as a circuit for specific applications.

### Film-forming method

### First example

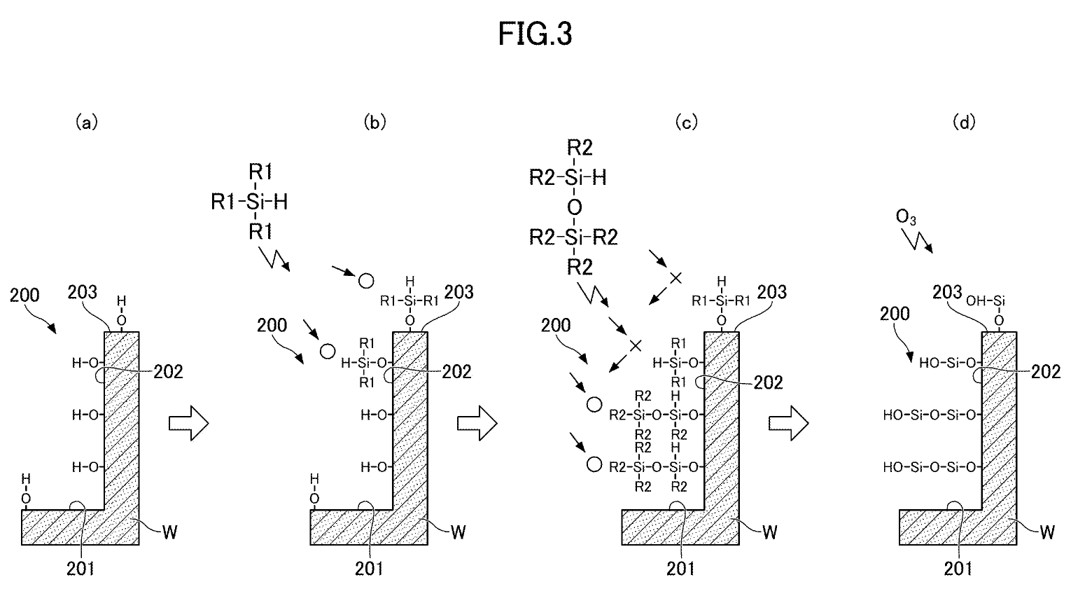

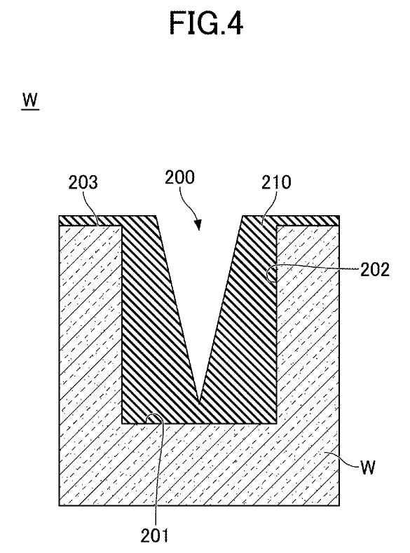

FIGS. 3 and 4 are cross-sectional diagrams of a first example of a film-forming method according to an embodiment of the present disclosure. The following description will be made taking, as an example, a case in which a silicon oxide film is formed in a recess 200 formed in the surface of the substrate W in the film-forming apparatus 100 described above. In the first example, the first silicon raw material is a silicon-containing gas containing one silicon (Si) atom in one molecule thereof, the second silicon raw material is a silicon-containing gas containing two silicon atoms in one molecule thereof, the oxidizing agent is an ozone gas, and the purge gas and the separation gas are each a nitrogen gas. Examples of the silicon-containing gas containing one silicon atom in one molecule thereof include, for example: aminosilane-based gases, such as a tris-dimethylaminosilane (TDMAS) gas, a diisopropylaminosilane (DIPAS) gas, a bis(tert-butylamino)silane (BTBAS) gas, and the like; and chlorosilane-based gases, such as a dichlorosilane (DCS) gas, a trichlorosilane (TrCS) gas, and the like. Examples of the silicon-containing gas containing two silicon atoms in one molecule thereof include a hexachlorodisilane (HCD) gas and the like.

First, the controller 110 controls the film-forming apparatus 100 to place the substrate W on each stage 24 of the rotary table 2 in the processing chamber 1. As illustrated in (a) of FIG. 3, the recess 200, such as a trench, a hole, or the like, is formed in the surface of the substrate W. The recess 200 includes a bottom surface 201, a side surface 202, and a top surface 203. For example, OH groups are formed on the bottom surface 201, the side surface 202, and the top surface 203. The bottom surface 201 and a lower portion of the side surface 202 form a lower portion of the recess 200, and the top surface 203 and an upper portion of the side surface 202 form an upper portion of the recess 200.

Next, the controller 110 controls the valves VA6 and VB6 and the flow rate controller FC6 to supply a nitrogen gas from the separation gas nozzle 41 to the separation region D1. Also, the controller 110 controls the valves VA7 and VB7 and the flow rate controller FC7 to supply a nitrogen gas from the separation gas nozzle 42 to the separation region D2. Also, the controller 110 controls valves (not shown) and a flow rate controller (not shown) to supply a nitrogen gas from the separation gas supply tube 16 and the purge gas supply tubes 17 and 27 into the processing chamber 1. Also, the controller 110 controls the pressure controller 65 such that the internal pressure of the processing chamber 1 reaches a desired pressure. Also, the controller 110 controls the driver 23 to rotate the rotary table 2 clockwise at a desired rotation speed. Also, the controller 110 controls the heater 7 such that the temperature of the substrate W reaches a desired temperature.

Next, the controller 110 controls the valves VA1 and VB1 and the flow rate controller FC1 to supply the first silicon raw material from the processing gas nozzle 31 to the first processing region P1. Thus, in the first processing region P1, the first silicon raw material is adsorbed selectively onto the upper portion of the recess 200 of the substrate W, as illustrated in (b) of FIG. 3. In (b) of FIG. 3, substituents included in the first silicon raw material are denoted by -R1. All the substituents -R1 included in the first silicon raw material may be the same, or some of the substituents -R1 may be different from the other. For example, by adjusting the flow rate of the first silicon raw material, the rotation speed of the rotary table 2, the internal pressure of the processing chamber 1, and the like, it is possible to adsorb the first silicon raw material selectively onto the upper portion of the recess 200.

The controller 110 controls the valves VA2 and VB2 and the flow rate controller FC2 to supply the second silicon raw material from the processing gas nozzle 32 to the second processing region P2. Thus, in the second processing region P2, the second silicon raw material is adsorbed onto a region in the recess 200 where the first silicon raw material is not adsorbed, as illustrated in (c) of FIG. 3. In (c) of FIG. 3, substituents included in the second silicon raw material are denoted by -R2. All the substituents -R2 included in the second silicon raw material may be the same, or some of the substituents -R2 may be different from the other. In the substrate W moved from the first processing region P1 to the second processing region P2 in accordance with the rotation of the rotary table 2, the first silicon raw material is adsorbed onto the upper portion of the recess 200. The second silicon raw material tends to be adsorbed to the OH groups, and tends not to be adsorbed in the region where the first silicon raw material is adsorbed. Therefore, as illustrated in (c) of FIG. 3, the adsorption of the second silicon raw material onto the upper portion of the recess 200 is inhibited, and the second silicon raw material is adsorbed onto the lower portion of the recess 200. For example, by increasing the flow rate of the second silicon raw material compared to the flow rate of the first silicon raw material, the second silicon raw material can readily reach the lower portion of the recess 200, i.e., the second silicon raw material can be readily adsorbed onto the lower portion of the recess 200.

The controller 110 controls the valves VA3 and VB3 and the flow rate controller FC3 to supply an ozone gas from the processing gas nozzle 33 to the third processing region P3. Thus, in the third processing region P3, the first silicon raw material adsorbed onto the upper portion of the recess 200 and the second silicon raw material adsorbed onto the lower portion of the recess 200 are oxidized, as illustrated in (d) of FIG. 3. Here, as described above, the first silicon raw material contains one silicon atom in one molecule thereof, and the second silicon raw material contains two silicon atoms in one molecule thereof. Therefore, the number of SiO layers stacked in the lower portion of the recess 200 is twice as many as the number of SiO layers stacked in the upper portion of the recess 200.

The controller 110 controls the driver 23 to continue the rotation of the rotary table 2. Thus, with the temperature of the substrate W being maintained at a desired temperature, the adsorption of the first silicon raw material onto the upper portion of the recess 200, the adsorption of the second silicon raw material onto the lower portion of the recess 200, and the oxidation of the first silicon raw material and the second silicon raw material are repeatedly performed such that the adsorption of the first silicon raw material is followed by the adsorption of the second silicon raw material, and the adsorption of the second silicon raw material is followed by the oxidation of the first silicon raw material and the second silicon raw material. As a result, as illustrated in FIG. 4, a silicon oxide film 210 having a desired film thickness is formed over the surface of the recess 200. Here, as described above, the first silicon raw material contains one silicon atom in one molecule thereof, and the second silicon raw material contains two silicon atoms in one molecule thereof. Therefore, the number of SiO layers stacked in the lower portion of the recess 200 is twice as many as the number of SiO layers stacked in the upper portion of the recess 200. As a result, the silicon oxide film 210 can be formed to be thicker in the lower portion of the recess 200 than in the upper portion of the recess 200.

When the film thickness of the silicon oxide film 210 reaches a desired thickness, the controller 110 controls the valves VA1 to VA3, the valves VB1 to VB3, and the flow rate controllers FC1 to FC3 to stop the supply of the gases from the processing gas nozzles 31, 32, and 33. Also, the controller 110 controls the valves VA6 and VA7, the valves VB6 and VB7, and the flow rate controllers FC6 and FC7 to stop the supply of the nitrogen gas from the separation gas nozzles 41 and 42. Also, the controller 110 controls the valves and the flow rate controller to stop the supply of the nitrogen gas from the separation gas supply tube 16 and the purge gas supply tubes 17 and 27.

Next, the controller 110 controls the film-forming apparatus 100 to transfer the substrate W, placed on each stage 24 of the rotary table 2 in the processing chamber 1, out of the processing chamber 1.

In the example of FIGS. 3 and 4, the first silicon raw material is a silicon raw material containing one silicon atom in one molecule thereof, and the second silicon raw material is a silicon raw material containing two silicon atoms in one molecule thereof. However, this is by no means a limitation. For example, the first silicon raw material may be a silicon raw material containing one silicon atom in one molecule thereof, and the second silicon raw material may be a silicon raw material containing three or more silicon atoms in one molecule thereof. For example, the first silicon raw material may be a silicon raw material containing two silicon atoms in one molecule thereof, and the second silicon raw material may be a silicon raw material containing three or more silicon atoms in one molecule thereof. In this manner, the number of silicon atoms contained in one molecule of the second silicon raw material is greater than the number of silicon atoms contained in one molecule of the first silicon raw material. In this case, the silicon oxide film 210 can be formed to be thicker in the lower portion of the recess 200 than in the upper portion of the recess 200.

Further, for example, the number of silicon atoms contained in one molecule of the first silicon raw material may be greater than the number of silicon atoms contained in one molecule of the second silicon raw material. In this case, the silicon oxide film 210 can be formed to be thicker in the upper portion of the recess 200 than in the lower portion of the recess 200.

As described above, in the first example of the film-forming method according to the embodiment, the number of silicon atoms contained in one molecule of the first silicon raw material is different from the number of silicon atoms contained in one molecule of the second silicon raw material. Thus, it is possible to control the fill profile when filling the silicon oxide film 210 into the recess 200.

### Second example

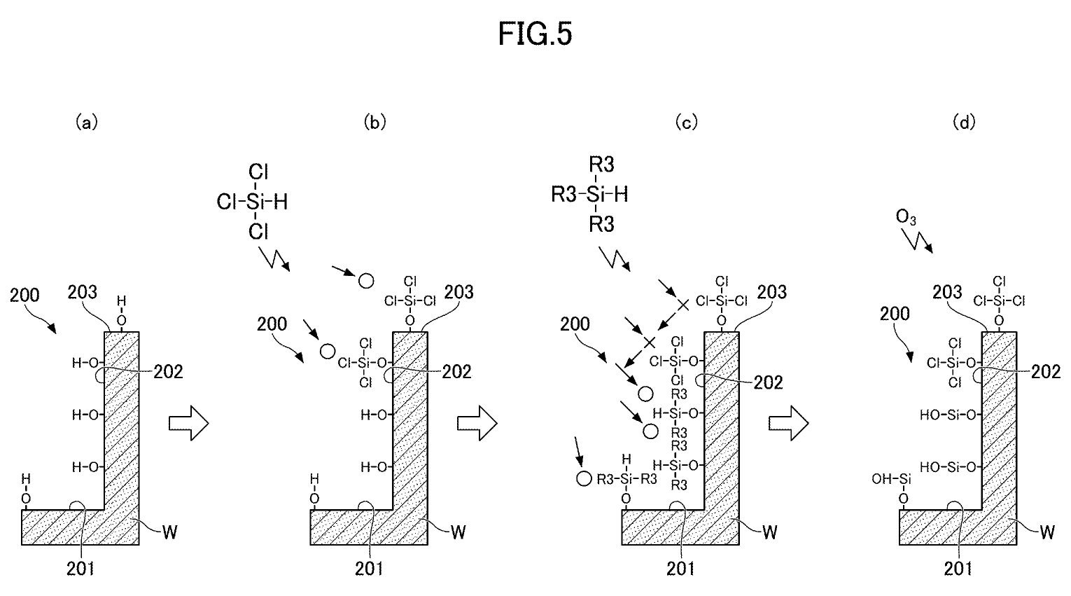

FIG. 5 is a cross-sectional diagram of a second example of the film-forming method according to the embodiment. The following description will be made taking, as an example, a case in which a silicon oxide film is formed in the recess 200 formed in the surface of the substrate W in the film-forming apparatus 100 described above. In the second example, the first silicon raw material is a chlorosilane-based gas, the second silicon raw material is an aminosilane-based gas, the oxidizing agent is an ozone gas, and the purge gas and the separation gas are each a nitrogen gas. Examples of the chlorosilane-based gas include a dichlorosilane (DCS) gas, a trichlorosilane (TrCS) gas, and a hexachlorodisilane (HCD) gas. Examples of the aminosilane-based gas include a tris-dimethylaminosilane (TDMAS) gas, a diisopropylaminosilane (DIPAS) gas, and a bis(tert-butylamino)silane (BTBAS) gas.

First, the controller 110 controls the film-forming apparatus 100 to place the substrate W on each stage 24 of the rotary table 2 in the processing chamber 1. As illustrated in (a) of FIG. 5, the recess 200, such as a trench, a hole, or the like, is formed in the surface of the substrate W. The recess 200 includes the bottom surface 201, the side surface 202, and the top surface 203. For example, OH groups are formed on the bottom surface 201, the side surface 202, and the top surface 203. The bottom surface 201 and a lower portion of the side surface 202 form a lower portion of the recess 200, and the top surface 203 and an upper portion of the side surface 202 form an upper portion of the recess 200.

Next, the controller 110 controls the valves VA6 and VB6 and the flow rate controller FC6 to supply a nitrogen gas from the separation gas nozzle 41 to the separation region D1. Also, the controller 110 controls the valves VA7 and VB7 and the flow rate controller FC7 to supply a nitrogen gas from the separation gas nozzle 42 to the separation region D2. Also, the controller 110 controls valves (not shown) and a flow rate controller (not shown) to supply a nitrogen gas from the separation gas supply tube 16 and the purge gas supply tubes 17 and 27 into the processing chamber 1. Also, the controller 110 controls the pressure controller 65 such that the internal pressure of the processing chamber 1 reaches a desired pressure. Also, the controller 110 controls the driver 23 to rotate the rotary table 2 clockwise at a desired rotation speed. Also, the controller 110 controls the heater 7 such that the temperature of the substrate W reaches a desired temperature.

Next, the controller 110 controls the valves VA1 and VB1 and the flow rate controller FC1 to supply the first silicon raw material from the processing gas nozzle 31 to the first processing region P1. Thus, in the first processing region P1, the first silicon raw material is adsorbed selectively on the upper portion of the recess 200 of the substrate W, as illustrated in (b) of FIG. 5. For example, by adjusting the flow rate of the first silicon raw material, the rotation speed of the rotary table 2, the internal pressure of the processing chamber 1, and the like, it is possible to adsorb the first silicon raw material selectively on the upper portion of the recess 200.

The controller 110 controls the valves VA2 and VB2 and the flow rate controller FC2 to supply the second silicon raw material from the processing gas nozzle 32 to the second processing region P2. Thus, in the second processing region P2, the second silicon raw material is adsorbed onto a region in the recess 200 where the first silicon raw material is not adsorbed, as illustrated in (c) of FIG. 5. In (c) of FIG. 5, substituents included in the second silicon raw material are denoted by -R3. All the substituents -R3 included in the second silicon raw material may be the same, or some of the substituents -R3 may be different from the other. In the substrate W moved from the first processing region P1 to the second processing region P2 in accordance with the rotation of the rotary table 2, the first silicon raw material is adsorbed onto the upper portion of the recess 200. The second silicon raw material tends to be adsorbed to the OH groups, and tends not to be adsorbed to chlorine terminated-sites (Cl). Therefore, as illustrated in (c) of FIG. 5, the adsorption of the second silicon raw material onto the upper portion of the recess 200 is inhibited, and the second silicon raw material is adsorbed onto the lower portion of the recess 200.

The controller 110 controls the valves VA3 and VB3 and the flow rate controller FC3 to supply an ozone gas from the processing gas nozzle 33 to the third processing region P3. Thus, in the third processing region P3, the oxidation of the first silicon raw material is inhibited by the chlorine terminated-sites included in the first silicon raw material adsorbed onto the upper portion of the recess 200, and the oxidation of the second silicon raw material adsorbed onto the lower portion of the recess 200 is performed, as illustrated in (d) of FIG. 5. In the substrate W moved from the second processing region P2 to the third processing region P3 in accordance with the rotation of the rotary table 2, there are many Si-H bonds in the lower portion of the recess 200, while there are many Si-Cl bonds in the upper portion of the recess 200. The binding energy of the Si-Cl bond is greater than the binding energy of the Si-H bond. Therefore, when an ozone gas is supplied to the substrate W, the TDMAS gas adsorbed onto the lower portion of the recess 200 is more likely to react with the ozone gas than does the TDMAS gas adsorbed onto the upper portion of the recess 200. As a result, the TDMAS gas adsorbed onto the lower portion of the recess 200 is selectively oxidized, thereby forming OH groups selectively in the lower portion of the recess 200.

The controller 110 controls the driver 23 to continue the rotation of the rotary table 2. Thus, with the temperature of the substrate W being maintained at a desired temperature, the adsorption of the first silicon raw material onto the upper portion of the recess 200, the adsorption of the second silicon raw material onto the lower portion of the recess 200, and the oxidation of the second silicon raw material are repeatedly performed such that the adsorption of the first silicon raw material is followed by the adsorption of the second silicon raw material, and the adsorption of the second silicon raw material is followed by the oxidation of the second silicon raw material. As a result, the silicon oxide film 210 having a desired film thickness is formed over the surface of the recess 200. Here, as described above, the first silicon raw material is a chlorosilane-based gas, and the second silicon raw material is an aminosilane-based gas. Therefore, while inhibiting oxidation of the first silicon raw material gas in the upper portion of the recess 200, the second silicon raw material can be oxidized in the lower portion of the recess 200. As a result, the silicon oxide film 210 can be formed to be thicker in the lower portion of the recess 200 than in the upper portion of the recess 200.

When the film thickness of the silicon oxide film 210 reaches a desired thickness, the controller 110 controls the valves VA1 to VA3, the valves VB1 to VB3, and the flow rate controllers FC1 to FC3 to stop the supply of the gases from the processing gas nozzles 31, 32, and 33. Also, the controller 110 controls the valves VA6 and VA7, the valves VB6 and VB7, and the flow rate controllers FC6 and FC7 to stop the supply of the nitrogen gas from the separation gas nozzles 41 and 42. Also, the controller 110 controls the valves and the flow rate controller to stop the supply of the nitrogen gas from the separation gas supply tube 16 and the purge gas supply tubes 17 and 27.

Next, the controller 110 controls the film-forming apparatus 100 to transfer the substrate W, placed on each stage 24 of the rotary table 2 in the processing chamber 1, out of the processing chamber 1.

In the example of FIG. 5, the first silicon raw material is a chlorosilane-based gas, and the second silicon raw material is an aminosilane-based gas. However, this is by no means a limitation. The second silicon raw material may be a silicon raw material having an oxidation rate with respect to an ozone gas higher than an oxidation rate of the first silicon raw material with respect to an ozone gas. In this case, the silicon oxide film 210 can be formed to be thicker in the lower portion of the recess 200 than in the upper portion of the recess 200. For example, the first silicon raw material may be a silane-based gas including a halogen, and the second silicon raw material may be a silane-based gas free from a halogen.

Further, for example, the second silicon raw material may be a silicon raw material that includes silicon atoms in one molecule thereof more than silicon atoms in one molecule of the first silicon raw material, and has an oxidation rate with respect to an ozone gas higher than an oxidation rate of the first silicon raw material with respect to an ozone gas. In this case, the silicon oxide film 210 can be formed to be especially thicker in the lower portion of the recess 200 than in the upper portion of the recess 200.

Further, for example, the first silicon raw material may have an oxidation rate with respect to an ozone gas higher than an oxidation rate of the second silicon raw material with respect to an ozone gas. In this case, the silicon oxide film 210 can be formed to be thicker in the upper portion of the recess 200 than in the lower portion of the recess 200.

As described above, in the second example of the film-forming method according to the embodiment, the oxidation rate of the first silicon raw material with respect to the ozone gas is different from the oxidation rate of the second silicon raw material with respect to the ozone gas. Thus, it is possible to control the fill profile when filling the silicon oxide film 210 into the recess 200.

### Experiment

In an experiment, the effect of the type of the silicon raw material on a cycle rate of the silicon oxide film 210 was evaluated.

In the experiment, the silicon oxide film 210 was formed by repeatedly performing the adsorption of the silicon raw material onto the substrate W and the oxidation of the silicon raw material such that the adsorption of the silicon raw material was followed by the oxidation of the silicon raw material. Also, the cycle rate of the silicon oxide film 210 was calculated by measuring the film thickness of the formed silicon oxide film 210. The cycle rate refers to a film thickness of the silicon oxide film 210 formed by performing one cycle of the adsorption of the silicon raw material onto the substrate W and the oxidation of the silicon raw material.

In the experiment, the substrate W including a silicon oxide film formed over the surface was used, a TDMAS gas and a TrCS gas were used as silicon raw materials, and a gas mixture of a hydrogen gas and an oxygen gas was used as an oxidizing agent. In the experiment, the temperature of the substrate W was set to 760 degrees Celsius (°C), and the internal pressure of the processing chamber 1 was set to 6.7 Torr.

As a result of the experiment, the cycle rate with the silicon raw material being the TrCS gas was about 0.4 times as high as the cycle rate with the silicon raw material being the TDMAS gas. This result confirms that the cycle rate of the silicon oxide film 210 can be changed by changing the type of the silicon raw material.

The embodiments disclosed herein are exemplary in all respects and are not restrictive. In the above-described embodiments, omissions, substitutions, or modifications may be possible in various forms without departing from the scope and intent of claims recited.

The above embodiments have been described using the case in which the oxidizing agent is an ozone gas or a gas mixture of a hydrogen gas and an oxygen gas. However, the present disclosure is not limited to this. The oxidizing agent may be a hydrogen peroxide gas. Also, a plasma may be generated from the oxidizing agent.

According to the present disclosure, it is possible to provide a technique of controlling a fill profile when filling a silicon oxide film into a recess.

What is claimed is:

1. A film-forming method, comprising:
supplying a first silicon raw material to a substrate having a recess such that the first silicon raw material is adsorbed selectively onto an upper portion of the recess;
supplying a second silicon raw material to the substrate such that the second silicon raw material is absorbed onto a region of the recess where the first silicon raw material is not absorbed;
oxidizing the second silicon raw material adsorbed onto the recess by supplying an oxidizing agent to the substrate; and
repeatedly performing the adsorption of the first silicon raw material, the adsorption of the second silicon raw material, and the oxidization of the second silicon raw material such that the adsorption of the first silicon raw material is followed by the adsorption of the second silicon raw material, and the adsorption of the second silicon raw material is followed by the oxidization of the second silicon raw material.

2. The film-forming method according to claim 1, wherein
a number of silicon atoms included in one molecule of the second silicon raw material is greater than a number of silicon atoms included in one molecule of the first silicon raw material.

3. The film-forming method according to claim 2, wherein
the first silicon raw material includes one silicon atom in one molecule of the first silicon raw material, and
the second silicon raw material includes two or more silicon atoms in one molecule of the second silicon raw material.

4. The film-forming method according to claim 1, wherein
an oxidation rate of the second silicon raw material with respect to the oxidizing agent is higher than an oxidation rate of the first silicon raw material with respect to the oxidizing agent.

5. The film-forming method according to claim 4, wherein
the first silicon raw material includes a halogen, and
the second silicon raw material is free from the halogen.

6. The film-forming method according to claim 5, wherein
the first silicon raw material includes a chlorosilane-based gas, and
the second silicon raw material includes an aminosilane-based gas.

7. The film-forming method according to claim 1, wherein
the adsorption of the first silicon raw material, the adsorption of the second silicon raw material, and the oxidization of the second silicon raw material are performed with the substrate being maintained at the same temperature.

8. The film-forming method according to claim 1,
wherein
the adsorption of the first silicon raw material, the adsorption of the second silicon raw material, and the oxidization of the second silicon raw material are performed by placing the substrate on a rotary table provided in a processing chamber along a circumferential direction of the rotary table, and causing the placed substrate to pass through a first processing region, a second processing region, and a third processing region in accordance with rotation of the rotary table, and
wherein
the first processing region, the second processing region, and the third processing region are spaced apart from each other along a rotation direction of the rotary table,
the first processing region is configured to perform the adsorption of the first silicon raw material,
the second processing region is configured to perform the adsorption of the second silicon raw material, and
the third processing region is configured to perform the oxidization of the second silicon raw material.

9. A film-forming apparatus configured to form a silicon oxide film, the film-forming apparatus comprising:
a controller including circuitry configured to control the film-forming apparatus to perform:
supplying a first silicon raw material to a substrate having a recess such that the first silicon raw material is adsorbed selectively onto an upper portion of the recess;
supplying a second silicon raw material to the substrate such that the second silicon raw material is absorbed onto a region of the recess where the first silicon raw material is not absorbed;
oxidizing the second silicon raw material adsorbed onto the recess by supplying an oxidizing agent to the substrate; and
repeatedly performing the adsorption of the first silicon raw material, the adsorption of the second silicon raw material, and the oxidization of the second silicon raw material such that the adsorption of the first silicon raw material is followed by the adsorption of the second silicon raw material, and the adsorption of the second silicon raw material is followed by the oxidization of the second silicon raw material.
